(19) United States
(12) Patent Application Publication
(10) Pub. No.: US 2019/0162761 A1
(43) Pub. Date: May 30, 2019

(54) METHOD OF GENERATING ENERGY MAP AND APPARATUS USING THE SAME

(71) Applicant: ELECTRONICS AND TELECOMMUNICATIONS RESEARCH INSTITUTE, Daejeon (KR)

(72) Inventors: Tai-yeon KU, Daejeon (KR); Wan Ki PARK, Daejeon (KR); Chang-Sic CHOI, Daejeon (KR)

(21) Appl. No.: 16/193,083

(22) Filed: Nov. 16, 2018

(30) Foreign Application Priority Data
Nov. 24, 2017 (KR) 10-2017-0158839
Feb. 28, 2018 (KR) 10-2018-0024841

(51) Int. Cl. G01R 21/133

(52) U.S. Cl. CPC G01R 21/133; G06F 7/575

(57) ABSTRACT

A method of generating an energy map and an apparatus using the same. The method of generating an energy map includes acquiring a plurality of energy events and a situation event, arranging the plurality of energy events and the situation event temporally in an energy map in an order of occurrence, calculating a weight of the plurality of energy events and the situation event, and determining a correlation between the plurality of energy events and the situation event based on the weight.

### CROSS-REFERENCE TO RELATED APPLICATIONS

This application claims the priority benefit of Korean Patent Application Nos. 10-2017-0158839, filed Nov. 24, 2017, and 10-2018-0024841, filed Feb. 28, 2018, in the Korean Intellectual Property Office, the disclosures of which are incorporated herein by reference for all purposes.

### BACKGROUND

### 1. Field of the Invention

One or more example embodiments relate to a method of generating an energy map and an apparatus using the same.

### 2. Description of Related Art

As global warming and the severity of environmental pollution have gradually increased, people have come to appreciate the need for energy savings and greenhouse gas reduction around the world. To replace existing fossil fuels, various renewable energy sources such as solar light, solar heat, wind, geothermal, and other renewable energy have been proposed, and many investments and research activities are under way due to strong government support in the US and Europe including Korea.

Current power infrastructure is produced centrally through hydropower, thermal power, and nuclear power, and is then transmitted, transformed, and distributed. Recently, with the recognition of the deterioration of some electric power infrastructure and the recognition of the necessity of new and renewable energy, there is a need for a completely different electric power infrastructure. For example, there are families that install solar panels to supply energy or sell power to utility companies.

As such, although new energy is secured through various energy sources, the importance of efficient energy management is growing due to limited resources. Efficient energy management not only means cost savings but also estimating and preparing energy generation and energy consumption by identifying factors that may affect energy and predicting future behavior patterns through historical data.

Smart energy management service refers to service to develop smart energy platform technology to maximize energy efficiency through energy information collection, energy management, and energy sharing/trading. Users may use the smart energy management service to supply energy to devices connected to the Internet or interconnect energy systems. In addition, the users may use energy sharing and trading services using the smart energy management service, thereby improving energy efficiency.

### SUMMARY

According to an aspect, there is provided a method of generating an energy map, the method including acquiring a plurality of energy events and a situation event, arranging the plurality of energy events and the situation event temporally in an energy map in an order of occurrence, calculating a weight of the plurality of energy events and the situation event, and determining a correlation between the plurality of energy events and the situation event based on the weight.

The correlation may include at least one of a sequential relationship, an AND relationship, an OR relationship, an exclusive OR (XOR) relationship, a timer relationship, a racing relationship, a voting relationship, and a sum relationship and the weight includes at least one of a sequential weight, an AND weight, an OR weight, an XOR weight, a timer weight, a racing weight, a voting weight, and a sum weight.

The calculating of the weight may include calculating the weight based on a priority.

The sequential weight, the AND weight, the OR weight, the XOR weight, the timer weight may have priority levels in a descending order and the timer weight, the racing weight, the voting weight, and the sum weight may have a same priority level.

When a first energy event occurs and a second energy event sequentially occurs, the calculating of the weight may include adding a sequential weight for the second energy event of the first energy event.

When a first energy event and a second, energy event occur and a third energy event sequentially occurs, the calculating of the weight may include adding an AND weight for the first energy event and the second energy event of the third energy event.

When a first energy event or a second energy event occur and a third energy event sequentially occurs, the calculating of the weight may include adding an OR weight for the first energy event and the second energy event of the third energy event.

When one of a first energy event and a second energy event occurs and the other does not occur, and a third energy event sequentially occurs, the calculating of the weight may include adding an XOR weight for the first energy event and the second energy event of the third energy event.

When a first energy event occurs and a second energy event sequentially occurs after a first time elapses, the calculating of the weight may include setting the first time to be a timer weight for the second, energy event of the first energy event.

When a first energy event and a second energy event occur, and a third energy event sequentially occurs based on a value of an energy event occurring earlier between the first energy event and the second energy event, the calculating of the weight may include adding a racing weight for the first energy event and the second energy event of the third energy event.

When a first energy event, a second energy event, and a third energy event occur and a fourth energy event sequentially occurs based on a value of a most frequent energy event among a value of the first energy event, a value of the second energy event, and a value of the third energy event, the calculating of the weight may include adding a voting weight for the first energy event, the second energy event, and the third energy event of the fourth energy event.

When a first energy event, a second energy event, and a third energy event occur and a fourth energy event sequentially occurs in response to a sum of a value of the first energy event, a value of the second energy event, and a value of the third energy event being greater than or equal to a threshold, the calculating of the weight may include adding a sum weight for the first energy event, the second energy event, and the third energy event of the fourth energy event.

According to another aspect, there is provided an apparatus for generating an energy map, the apparatus including a communication module configured to acquire a plurality of energy events and a situation event and a controller configured to arrange the plurality of energy events and the situation event temporally in an energy map in an order of occurrence, calculate a weight of the plurality of energy events and the situation event, and determine a correlation between the plurality of energy events and the situation event based on the weight.

The correlation may include at least one of a sequential relationship, an AND relationship, an OR relationship, an exclusive OR (XOR) relationship, a timer relationship, a racing relationship, a voting relationship, and a sum relationship and the weight may include at least one of a sequential weight, an AND weight, an OR weight, an XOR weight, a timer weight, a racing weight, a voting weight, and a sum weight.

The controller may be configured to calculate the weight based on a priority.

The sequential weight, the AND weight, the OR weight, the XOR weight, the timer weight may have priority levels in a descending order and the timer weight, the racing weight, the voting weight, and the sum weight may have a same priority.

Additional aspects of example embodiments will be set forth in part in the description which follows and, in part, will be apparent from the description, or may be learned by practice of the disclosure.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a block diagram illustrating an energy system according to an example embodiment;

FIG. 2 is a block diagram illustrating an apparatus for generating an energy map of FIG. 1;

FIG. 3 is a diagram illustrating an example of an operation of a controller generating an energy map according to an example embodiment;

FIG. 4 is a diagram illustrating another example of an operation of a controller generating an energy map according to an example embodiment; and

FIG. 5 is a flowchart illustrating a method of generating an energy map according to an example embodiment.

### DETAILED DESCRIPTION

Hereinafter, example embodiments will be described in detail with reference to the accompanying drawings. It should be understood, however, that there is no intent to limit this disclosure to the particular example embodiments disclosed. On the contrary, example embodiments are to cover all modifications, equivalents, and alternatives falling within the scope of the example embodiments.

The terminology used herein is for the purpose of describing particular embodiments only and is not intended to be limiting. As used herein, the singular forms “a,” “an,” and “the,” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains. Terms, such as those defined in commonly used dictionaries, are to be interpreted as, having a meaning that is consistent with their meaning in the context of the relevant art, and are not to be interpreted in an idealized or overly formal sense unless expressly so defined herein.

Regarding the reference numerals assigned to the elements in the drawings, it should be noted that the same elements will be designated by the same reference numerals, wherever possible, even though they are shown in different drawings. Also, in the description of embodiments, detailed description of well-known related structures or functions will be omitted when it is deemed that such description will cause ambiguous interpretation of the present disclosure.

In the present disclosure, a module may be hardware that may perform a function and an operation for each name explained in the specification, a computer program code that may perform predetermined function and operation, or an electronic recordable medium, for example, a processor and a microprocessor, including a computer program code for performing predetermined function and operation.

Accordingly, the module may indicate a functional and/or structural combination of hardware for performing technical ideas of the present disclosure and/or software for driving the hardware.

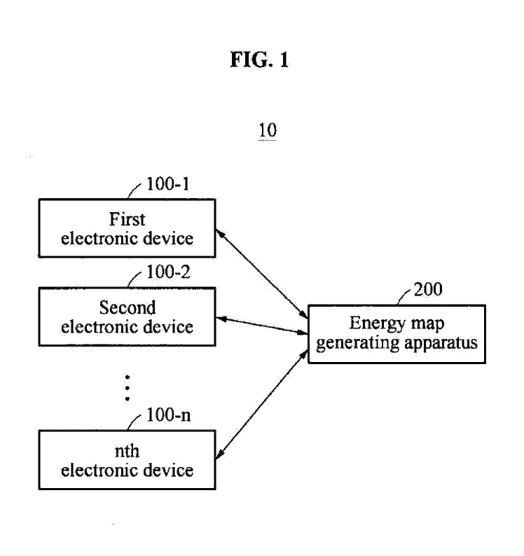

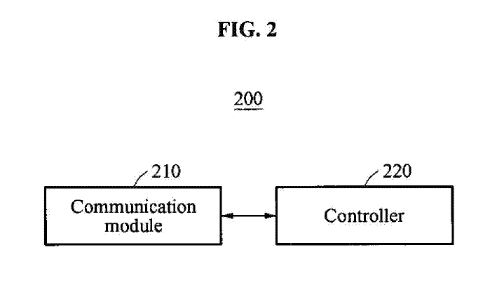

FIG. 1 is a block diagram illustrating an energy system according to an example embodiment and FIG. 2 is a block diagram illustrating an apparatus for generating an energy map of FIG. 1.

Referring to FIGS. 1 and 2, an energy system 10 may include a plurality of electronic devices 100-1 through 100-n and an energy map generating apparatus 200.

The plurality of electronic devices 100-1 through 100-n may include a first electronic device 100-1, a second electronic device 100-2, . . . , and an n^{th} electronic device 100-n. In this example, each of the plurality of electronic devices 100-1 through 100-n may be arranged to share the same environment with a different energy apparatus. For example, the first electronic device 100-1 and a first energy apparatus may exist in the same environment, the second electronic device 100-2 and a second energy apparatus may exist in the same environment, the a n^{th} electronic device 100-n and an n^{th} energy apparatus may exist in the same environment. The plurality of electronic devices 100-1 through 100-n may be implemented to use the Internet of things (IoTs).

The energy apparatus may be an apparatus related to an energy such as an energy source, a watt hour meter, and an energy storage system (ESS). The energy source may refer to a power plant using thermal, hydro, nuclear, solar light, solar heat, wind, or geothermal power.

Each of the plurality of electronic devices 100-1 through 100-n may acquire energy information data from the corresponding energy apparatus. The energy information data includes an energy event and a situation event. The energy event may be energy information such as time, temperature, humidity, brightness, an amount of power, and an operation of the energy device. The situation event may be situation information that may affect the energy apparatus, such as power outages and abnormal temperature.

The plurality of electronic devices 100-1 through 100-n may transmit the energy information data to the energy map generating, apparatus 200. For example, the first electronic device 100-1 may transmit energy information data of the first energy apparatus to the energy map generating apparatus 200, the second electronic device 100-2 may transmit energy information data of the second energy apparatus to the energy map generating apparatus 200, and the n^{th} electronic device 100-n may transmit energy information data of the n^{th} energy apparatus to the energy map generating apparatus 200.

The energy map generating apparatus 200 may generate an energy map based on a plurality of energy information data. The energy map may be understood as a data correlation map for each time and space of the plurality of energy information data. The apparatus 200 may provide a user with the energy map such that the user grasps an organic relationship between the energy information data. Also, the user may estimate energy consumption, a generation amount of energy, an error, or a failure based on the energy map so as to efficiently cope therewith.

The energy map generating apparatus 200 may include a communication module 210 and a controller 220.

The communication module 210 may acquire a plurality of energy information data from the plurality of electronic devices 100-1 through 100-n and transmit the plurality of energy information data to the controller 220.

The controller 220 may generate an energy map based on the plurality of energy information data.

The controller 220 may arrange the plurality of energy information data, for example, a plurality of energy events temporally in the energy map in an order of occurrence. In this example, the controller 220 may set a sequential weight for the sequentially occurring energy information data, to be 1.

The controller 220 may calculate a weight of the plurality of energy events and a situation event, and determine a correlation between the plurality of energy events and the situation event based on the weight.

For example, the correlation may include at least one of a sequential relationship, an AND relationship, an OR relationship, an exclusive OR (XOR) relationship, a timer relationship, a racing relationship, a voting relationship, and a sum relationship.

Also, the weight may include at least one of a sequential weight, an AND weight, an OR weight, an XOR weight, a timer weight, a racing weight, a voting weight, and a sum weight.

When calculating the weight, the controller 220 may perform calculation based on a priority. The sequential weight, the AND weight, the OR weight, the XOR weight, the timer weight may have priority levels in a descending order. Also, the timer weight, the racing weight, the voting, weight, and the sum weight may have a same priority.

The controller 220 may correct the weight and the correlation every time that the energy event and the situation event occur. That is, the controller 220 may perform repetitive learning, thereby performing estimation with increased precision and accuracy.

An operation of the controller 220 generating the energy map will be further described with the following drawings.

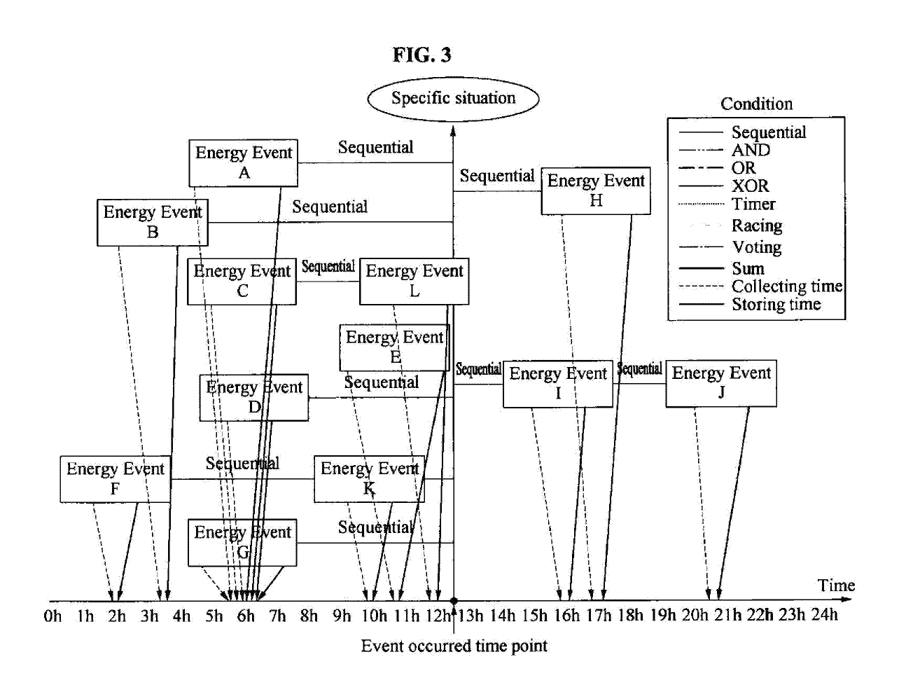

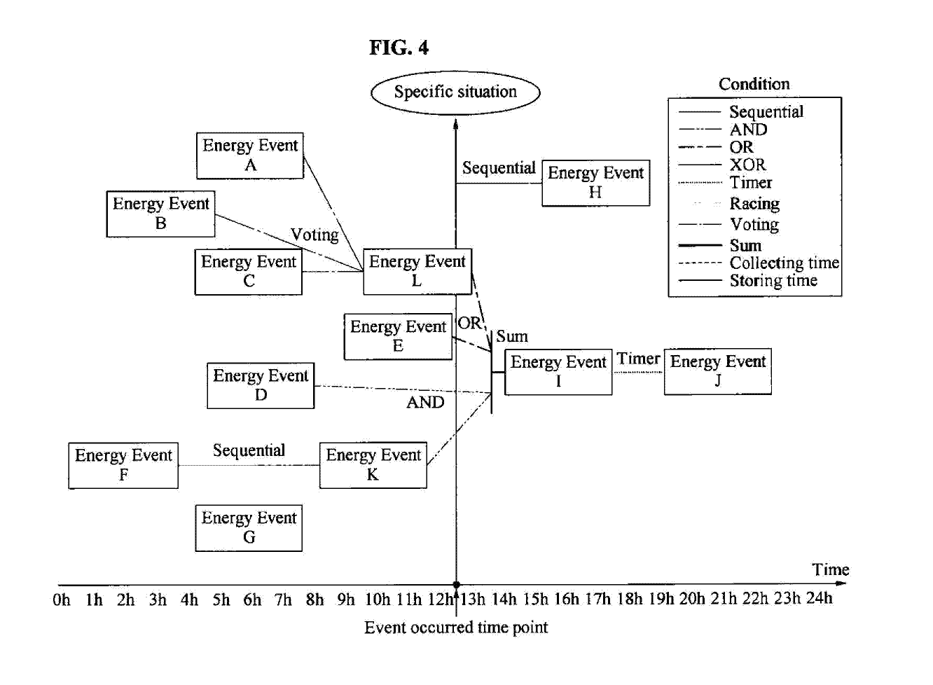

FIG. 3 is a diagram illustrating an example of an operation of a controller generating an energy map according to an example embodiment and FIG. 4 is a diagram illustrating another example of an operation of a controller generating an energy map according to an example embodiment.

Referring to FIG. 3, the controller 220 may arrange a plurality of energy information data temporally in an energy map. For example, the plurality of energy information data may include energy events A, B, C, D, E, F, G, H, I, J, K, and L, and a situation event corresponding to a specific situation. The plurality of energy information data may include time information and space information. The controller 220 may record a collecting time and a storing time of the plurality of energy information data.

The controller 220 may calculate a weight of the plurality of energy information data. The weight may include at least one of a sequential weight, an AND weight, an OR weight, an XOR weight, a timer weight, a racing weight, a voting weight, and a sum weight.

In this example, the controller 220 may set a sequential weight for the sequentially occurring energy information data, to be 1. When first energy information data is generated and second energy information data is sequentially is generated, a sequential weight for the second energy information data of the first energy information data may be defined as 1. In this example, a sequential weight for the first energy information data of the second energy information data may be defined as −1.

For example, when the energy event A occurs and the specific situation sequentially occurs, the controller 220 may set a sequential weight for the specific situation of the energy event A to be 1. Likewise, the controller 220 may seta sequential weight for the specific situation of the energy event B to be 1, set a sequential weight for the specific situation of the energy event D to be 1, and set a sequential weight for the specific, situation of the energy event G to be 1.

When the energy event C occurs and the energy event L sequentially occurs, the controller 220 may set a sequential weight for the energy event L of the energy event C to be 1. Likewise, the controller 220 may set a sequential weight for the energy event K of the energy event to be 1. In this example, when the energy event K occurs and the specific situation sequentially occurs, the controller 220 may set a sequential weight for the specific situation of the energy event K to be 1.

When the specific situation occurs and the energy event H sequentially occurs, the controller 220 may set a sequential weight for the energy event H of the specific situation to be 1. Likewise, the controller 220 may set a sequential weight for the energy event I of the specific situation to be 1. In this example, when the energy event I occurs and the energy event J sequentially occurs, the controller 220 may set a sequential weight for the energy event J of the energy event I to be 1.

The controller 220 may initially set 0 for other weights.

The controller 220 may set an AND weight for the energy information data sequentially generated under an AND condition to be 1. When the first energy information data and the second energy information data are generated and the third energy information data is sequentially is generated, an AND weight for the first energy information data and the second energy information data of the third energy information data may be defined as 1.

The controller 220 set an OR weight for the energy information data sequentially generated under an OR condition to be 1. When the first energy information data or the second energy information data is, generated and the third energy information data is sequentially generated, an OR weight for the first, energy information data and the second energy information data of the third energy information data may be defined as 1.

The controller 220 set an XOR weight for the energy information data sequentially generated under an XOR condition to be 1. When one of the first energy information data and the second energy information data is generated and the other is not generated, and the third energy information data is sequentially generated, an XOR weight for the first energy information data and the second energy information data of the third energy information data may be defined as 1.

The controller 220 may set a timer weight for the energy information data sequentially generated at preset time intervals. When the first energy information data is generated and the second energy information data is sequentially generated after a first time elapses, a timer weight for the second energy information data of the first energy information data may be defined as the first time.

When later energy information data is generated based on a value of earliest energy information data, the controller 220 may set a racing weight to be 1. When the first energy information data and the second energy information data are generated, and the third energy information data is sequentially generated based on a value of energy information data generated earlier between the first energy information data and the second energy information data, a racing weight for the first energy information data and the second energy information data of the third energy information data may be defined as 1.

When later energy information data is generated based on a value of energy information data that is the most frequently generated, the controller 220 may set a voting weight to be 1. When the first energy information data, the second energy information data, and the third energy information data are generated and fourth energy information data is sequentially generated based on a value of energy information data that is the most frequently generated among a value of the first energy information data, a value of the second energy information data, and a value of the third energy information data, a voting weight for the first energy information data, the second energy information data, and the third energy information data of the fourth energy information data may be defined as 1.

When later energy information data is generated based on a sum of values of energy information data, the controller 220 may set a sum weight to be 1. When the first energy information data, the second energy information data, and the third energy information data are generated and the fourth energy information data is sequentially generated in response to a sum of a value of the first energy information data, a value of the second energy information data, and a value of the third energy information data being greater than or equal to a threshold, a sum weight for the first energy information data, the second energy information data, and the third energy information data of the fourth energy information data may be defined as 1.

Also, the controller 220 may calculate the weight based on a priority. In terms of the weight, the sequential weight, the AND weight, the OR weight, the XOR weight, the timer weight may have priority levels in a descending order. The timer weight, the racing weight, the voting weight, and the sum weight may have a same priority level.

When overlapping weights of the energy information data are generated, the controller 220 may calculate a weight having a higher priority level. For example, when the first energy information data is generated and, the second energy information data is sequentially generated, the controller 220 sets a sequential weight for the first energy information data of the second energy information data to be 1. Also, when the third energy information data is generated and the second energy information data is sequentially generated, the controller 220 may set a sequential weight for the third energy information data of the second energy information data to be 1. In this example, when the first energy information data and the third energy information data are simultaneously generated to generate the second energy information data, the controller 220 may set an AND weight for the first energy information data and the third energy information data of the second energy information data to be 1. As described above, the AND weight may have a higher priority level than that of the sequential weight.

With reference to FIG. 4, an operation of the controller 220 of determining a correlation between a plurality of energy information data based on a priority and a weight will be described.

The controller 220 may determine a correlation of the energy event L with respect to the energy event A, the energy event B, and the energy event C to be a voting relationship.

The controller 220 may determine a correlation of the energy event H with respect to the specific situation to be a sequential relationship. Likewise, the controller 220 may determine a correlation of the energy event K with respect to the energy event F to be the sequential relationship.

The controller 220 may determine a correlation of the energy event I with respect to the energy event L, the energy event E, the energy event D, and the energy event K to be a sum relationship of an OR relationship between the energy event L and the energy event E and an AND relationship between the energy event D and the energy event K. That is, when the energy event D and the energy event K occur, and the energy event L or the energy event E occurs, the energy event I may sequentially occur in response to a sum of a value of the energy event L or a value of the energy event E, a value of the energy event D, and a value of the energy event K being greater than a threshold.

The controller 220 may determine a correlation of the energy event J with respect to the energy event I to be the voting relationship. For example, the energy event I may sequentially occur after a second time elapses from an occurrence of the energy event I. In this example, the second time may be a timer weight for the energy event I of the energy event J.

An operation of the controller 220 calculating the weight may be as shown in Table 1 below.

TABLE 1

| Condition | Weight | Description | Priority |
|---|---|---|---|
| Sequential(x,y) | If( time(x->y) ) SequentialWeight(x,y) +=1 | Occurring temporally | 4 |
| | else If( time(y->x) ) SequentialWeight(x,y) −=1 | and sequentially | |
| AND(z\|x,y) | if((sequential(x,z) and sequential(y,z)) then | Temporally occurring | 3 |
| | ANDWeight (z\|x,y) +=1, | after all the previous | |
| | ANDWeight(z\|y,x) += 1 | events occur | |
| OR(z\|x,y) | if((sequential(x,z) or sequential(y,z)) | Temporally occurring | 2 |
| | then ORWeight (z\|x,y) +=1, | when at least one of | |
| | ORWeight(\|y,x) += 1 | previous events occurs | |
| Timer(x,y) | If(sequential(x,y)) time(y)−time(x)= timerWeight | Sequentially occurring | 1 |
| | | after a preset time | |
| | | elapses from an | |
| | | occurrence of a | |
| | | previous event | |
| Racing(z\|x,y) | if((sequential(x,z) and sequential(y,z))and | Occurring due to | 1 |
| | (Value(z)== (Value(x)?Value(y)) | influence of event | |
| | Then Racing(z\|x,y)=Racing(z\|y,x)+=1 | having arrived earlier | |
| | | among previous | |
| | | events | |
| Voting(z\|x,y,w) | if((sequential(x,z) and sequential(y,z)and | Occurring based on | 1 |
| | sequential(w,z))and | the largest number of | |
| | countValue((Value(x),value(y),value(w))==value(z) | result values among | |
| | Then Voting(z\|x,y,z)+=1 | values of previous | |
| | | events | |
| Sum(z\|x,y,w) | if((sequential(x,z) and sequential(y,z)and | Occurring in response | 1 |
| | sequential(w,z))and | to a sum of result | |
| | sum((Value(x),value(y),value(w))==value(z) | values of previous | |
| | Then Sum(z\|x,y,z)+=1 | events being greater | |
| | | than or equal to a | |
| | | preset value | |

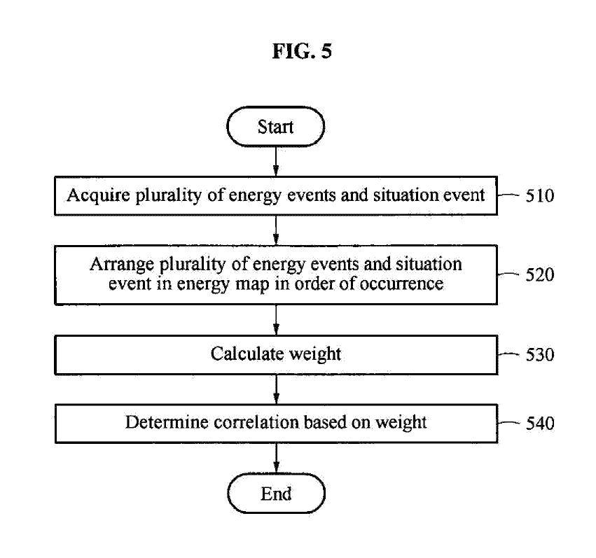

FIG. 5 is a flowchart illustrating a method of generating an energy map according to an example embodiment.

Referring to FIG. 5, in operation 510, an apparatus for generating an energy map may acquire a plurality of energy events and a situation event. In this example, the plurality of energy events and the situation event may be energy information data of an energy apparatus. The energy information data may include temporal and spatial information.

In operation 520, the apparatus may arrange the plurality of energy events and the situation event temporally in an energy map in an order of occurrence. Through this, a user may verify the energy events and the situation event in chronological, order.

In operation 530, the apparatus may calculate a weight of the plurality of energy events and the situation event. For example, the apparatus may calculate a weight between the plurality of energy events. Also, the apparatus may calculate weights between the plurality of energy events and the situation event. The weight may include, at least one of a sequential weight, an AND weight, an OR weight, an XOR weight, a timer weight, a racing weight, a voting weight, and a sum weight.

In operation 540, the apparatus may determine a correlation between the plurality of energy events and the situation event based on the weight. The correlation may include at least one of a sequential relationship, an AND relationship, an OR relationship, an XOR relationship, a timer relationship, a racing relationship, a voting relationship, and a sum relationship.

The apparatus may correct the weight and the correlation every time that the plurality of energy events and the situation event occur. That is, the apparatus may perform repetitive learning, thereby performing estimation with increased precision and accuracy.

The components described in the exemplary embodiments of the present invention may, be achieved by hardware components including at least one DSP (Digital Signal Processor), a processor, a controller, an ASIC (Application Specific Integrated Circuit), a programmable logic element such as an FPGA (Field Programmable Gate Array), other electronic devices, and combinations thereof. At least some of the functions or the processes described in the exemplary embodiments of the present invention may be achieved by software, and the software may be recorded on a recording medium. The components, the functions, and the processes described in the exemplary embodiments of the present invention may be achieved by a combination of hardware and software.

The processing device described herein may be implemented using hardware components, software components, and/or a combination thereof. For example, the processing device and the component described herein may be implemented using one or more general-purpose or special purpose computers, such as, for example, a processor, a controller and an arithmetic logic unit (ALU), a digital signal processor, a microcomputer, a field programmable gate array (FPGA), a programmable logic unit (PLU), a microprocessor, or any other device capable of responding to and executing instructions in a defined manner. The processing device may run an operating system (OS) and one or more software applications that run on the OS. The processing device also may access, store, manipulate, process, and create data in response to execution of the software. For purpose of simplicity, the description of a processing device is used as singular; however, one skilled in the art will be appreciated that a processing device may include multiple processing elements and/or multiple types of processing elements. For example, a processing device may include multiple processors or, a processor and a controller. In addition, different processing configurations are possible, such as parallel processors.

The methods according to the above-described example embodiments may be recorded in non-transitory computer-readable media including program instructions to implement various operations of the above-described example embodiments. The media may also include, alone or in combination with the program instructions, data files, data structures, and the like. The program instructions recorded on the media may be those specially designed and constructed for the purposes of example embodiments, or they may be of the kind well-known and available to those having skill in the computer software arts. Examples of non-transitory computer-readable media include magnetic media such as hard disks, floppy disks, and magnetic tape; optical media such as CD-ROM discs, DVDs, and/or Blue-ray discs; magneto-optical media such as optical discs; and hardware devices that are specially configured to store and perform program instructions, such as read-only memory (ROM), random access memory (RAM), flash memory (e.g., USB flash drives, memory cards, memory sticks, etc.), and the like. Examples of program instructions include both machine code, such as produced by a compiler, and files containing higher level code that may be executed by the computer using an interpreter. The above-described devices may be configured to act as one or more software modules in order to perform the operations of the above-described example embodiments, or vice versa.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A method of generating an energy map, the method comprising:
acquiring a plurality of energy events and a situation event;
arranging the plurality of energy events and the situation event temporally in an energy map in an order of occurrence;
calculating a weight of the plurality of energy events and the situation event; and
determining a correlation between the plurality of energy events and the situation event based on the weight.

2. The method of claim 1, wherein:
the correlation includes at least one of a sequential relationship, an AND relationship, an OR relationship, an exclusive OR (XOR) relationship, a timer relationship, a racing relationship, a voting relationship, and a sum relationship, and
the weight includes, at least one of a sequential weight, an AND weight, an OR weight, an XOR weight, a timer weight, a racing weight, a voting weight, and a sum weight.

3. The method of claim 2, wherein the calculating of the weight comprises:
calculating the weight based on a priority.

4. The method of claim 3, wherein:
the sequential weight, the AND weight, the OR weight, the XOR weight, the timer weight have priority levels in a descending order, and
the timer weight, the racing weight, the voting weight, and the sum weight have a same priority level.

5. The method of claim 1, wherein when a first energy event occurs and a second energy event sequentially occurs, the calculating of the weight comprises:
adding a sequential weight for the second energy event of the first energy event.

6. The method of claim 1, wherein when, a first energy event and a second energy event occur and a third energy event sequentially occurs, the calculating of the weight comprises:
adding an AND weight for the first energy event and the second energy event of the third energy event.

7. The method of claim 1, wherein when a first energy event or a second energy event occur and a third energy event sequentially occurs, the calculating of the weight comprises:
adding an OR weight for the first energy event and the second energy event of the third energy event.

8. The method of claim 1, wherein when one of a first energy event and a second energy event occurs and the other does not occur, and a third energy event sequentially occurs, the calculating of the weight comprises:
adding an XOR weight for the first energy event and the second energy event of the third energy event.

9. The method of claim 1, wherein when a first energy event occurs and a second energy event sequentially occurs after a first time elapses, the calculating of the weight comprises:
setting the first time to be a timer weight for the second energy event of the first energy event.

10. The method of claim 1, wherein when a first energy event and a second energy event occur, and a third energy event sequentially occurs based on a value of an energy event occurring earlier between the first energy event and the second energy event, the calculating of the weight comprises:
adding a racing weight for the first energy event and the second energy event of the third energy event.

11. The method of claim 1, wherein when a first energy event, a second energy event, and a third energy event occur and a fourth energy event sequentially occurs based on a value of a most frequent energy event among a value of the first energy event, a value of the second energy event, and a value of the third energy event, the calculating of the weight comprises:
adding a voting weight for the first energy event, the second energy event, and the third energy event of the fourth energy event.

12. The method of claim 1, wherein when a first energy event, a second energy event, and a third energy event occur and a fourth energy event sequentially occurs in response to a sum of a value of the first energy event, a value of the second energy event, and a value of the third energy event being, greater than or equal to a threshold, the calculating of the weight comprises:
adding a sum weight for the first energy event, the second energy event, and the third energy event of the fourth energy event.

13. An apparatus for generating an energy map, the apparatus comprising:
a communication module configured to acquire a plurality of energy events and a situation event; and
a controller configured to arrange the plurality of energy events and the situation event temporally in an energy map in an order of occurrence, calculate a weight of the plurality of energy events and the situation event, and determine a correlation between the plurality of energy events and the situation event based on the weight.

14. The apparatus of claim 13, wherein:
the correlation includes at least one of a sequential relationship, an AND relationship, an OR relationship, an exclusive OR (XOR) relationship, a timer relationship, a racing relationship, a voting relationship, and a sum relationship, and
the weight includes at least one of a sequential weight, an AND weight, an OR weight, an XOR weight, a timer weight, a racing weight, a voting weight, and a sum weight.

15. The apparatus of claim 14, wherein the controller is configured to calculate the weight based on a priority.

16. The apparatus of claim 15, wherein:
the sequential weight, the AND weight, the OR weight, the XOR weight, the timer weight have priority levels in a descending order, and
the timer weight, the racing weight, the voting weight, and the sum weight have a same priority.
